(19) United States
(12) Patent Application Publication
(10) Pub. No.: US 2025/0191889 A1
(43) Pub. Date: Jun. 12, 2025

(54) PLASMA PROCESSING APPARATUS AND SUBSTRATE PROCESSING SYSTEM

(71) Applicant: Tokyo Electron Limited, Tokyo (JP)

(72) Inventors: Ryutaro SUDA, Miyagi (JP); Koki TANAKA, Miyagi (JP); Kenta HORI, Miyagi (JP); Tomo MURAKAMI, Miyagi (JP); Shuji FUNADA, Miyagi (JP); Takuya HARASHIMA, Miyagi (JP); Ryu NAGAI, Miyagi (JP); Takashi KAKO, Miyagi (JP); Koji NIIYAMA, Miyagi (JP)

(73) Assignee: Tokyo Electron Limited, Tokyo (JP)

(21) Appl. No.: 19/059,696

(22) Filed: Feb. 21, 2025

Related U.S. Application Data
(63) Continuation of application No. PCT/JP2023/029709, filed on Aug. 17, 2023.

(30) Foreign Application Priority Data
Aug. 22, 2022 (JP) 2022-131692
Dec. 28, 2022 (JP) 2022-211539

(51) Int. Cl. H01J 37/32; H01L 21/311

(52) U.S. Cl. CPC H01J 37/32467; H01J 37/3244; H01J 37/32522; H01J 37/32862; H01J 2237/24585; H01J 2237/334; H01L 21/31116; H01L 21/31144

(57) ABSTRACT

A plasma processing apparatus includes: a chamber; a substrate support provided within the chamber; a gas supply port that is connected to a source of a processing gas containing hydrogen fluoride gas, and supplies the processing gas into the chamber; and a plasma generation unit that generates a plasma from the processing gas. At least a portion of the chamber is made of a material containing at least one material selected from carbon, tungsten, molybdenum, ruthenium, titanium nitride, samarium, and yttrium.

### CROSS-REFERENCE TO RELATED APPLICATIONS

This application is a continuation application of International Patent Application No. PCT/JP2023/029709, filed on Aug. 17, 2023, which claims priority from Japanese Patent Application Nos. 2022-131692 and 2022-211539, filed on Aug. 22, 2022 and Dec. 28, 2022, respectively, with the Japan Patent Office, the disclosure of each are incorporated herein in their entireties by reference.

### TECHNICAL FIELD

The present disclosure relates to a plasma processing apparatus and a substrate processing system.

### BACKGROUND

Japanese Patent Laid-Open Publication No. 2016-208034 discloses a technique for coating the inside of a plasma processing chamber.

### SUMMARY

An embodiment of the present disclosure provides a plasma processing apparatus that includes: a chamber; a substrate support unit provided within the chamber; a gas supply port connected to a supply source of a process gas containing hydrogen fluoride gas to supply the process gas into the chamber; and a plasma generation unit that generates a plasma from the process gas. At least a portion of the interior of the chamber is made of a material containing at least one material selected from carbon, tungsten, molybdenum, ruthenium, titanium nitride, samarium, and yttrium.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a configuration example of a plasma processing apparatus 1.

FIG. 2A is a view illustrating an example of the cross-sectional structure of a constituent member CP.

FIG. 2B is a view illustrating an example of the cross-sectional structure of the constituent member CP.

FIG. 2C is a view illustrating an example of the cross-sectional structure of the constituent member CP.

FIG. 2D is a view illustrating an example of the cross-sectional structure of the constituent member CP.

FIG. 3 is a view illustrating a flowchart of an example of the present processing method.

FIG. 4 is a view illustrating an example of the cross-sectional structure of a substrate W.

FIG. 5 is a view illustrating an example of the cross-sectional structure of the substrate W during the processing of step ST3.

FIG. 6 is a view illustrating the relationship between the flow rate of hydrogen fluoride gas and etching rate.

FIG. 7A is a view illustrating a time-dependent variation in HF intensity within a plasma processing space.

FIG. 7B is a view illustrating a time-dependent variation in SiF₃ intensity within the plasma processing space.

FIG. 7C is a view illustrating a time dependent variation in H₂ intensity in the plasma processing space.

FIG. 8 is a view schematically illustrating a substrate processing system PS.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, each embodiment of the present disclosure will be described.

In an embodiment, a plasma processing apparatus includes: a chamber; a substrate support unit provided within the chamber; a gas supply port that is connected to a source of a processing gas containing hydrogen fluoride gas, and supplies the processing gas into the chamber; and a plasma generation unit that generates a plasma from the processing gas. At least a portion of an interior of the chamber is made of a material containing at least one material selected from carbon, tungsten, molybdenum, ruthenium, titanium nitride, samarium, and yttrium.

In an embodiment, the material is a carbon-containing material.

In an embodiment, the carbon-containing material is at least one material selected from diamond, graphite, diamond-like carbon, silicon carbide, tungsten carbide, and boron carbide.

In an embodiment, the material is a tungsten-containing material.

In an embodiment, the tungsten-containing material is at least one material selected from tungsten carbide, tungsten silicide, tungsten oxide, tungsten nitride, tungsten silicon nitride, and tungsten silicon carbide.

In an embodiment, an area within the chamber exposed to the plasma is at least partially made of the material discussed above.

In an embodiment, an area in the chamber exposed to the plasma is entirely made of the material discussed above.

In an embodiment, the material is a tungsten-containing material.

In an embodiment, the chamber has an area made of a silicon-containing material, and the area is at least partially coated with the material discussed above.

In an embodiment, the coating is a deposited film or a thermally sprayed film containing at least one material selected from carbon, tungsten, molybdenum, ruthenium, titanium nitride, samarium, and yttrium.

In an embodiment, the chamber has a temperature-controllable area which is made of the material discussed above.

In an embodiment, the temperature-controllable area is in thermal contact with a flow path through which a heat transfer fluid flows.

In an embodiment, the plasma processing apparatus further includes: a showerhead disposed above the substrate support unit and provided with a plurality of gas supply ports, and the showerhead is at least partially made of the material discussed above.

In an embodiment, the plasma processing apparatus further includes: an edge ring disposed to surround the substrate disposed on the substrate support unit, and the edge ring is at least partially made of the material discussed above.

In an embodiment, an inner wall of the chamber is at least partially made of the material discussed above.

In an embodiment, the plasma processing apparatus further includes: a baffle plate that separates the interior of the chamber into a plasma processing space where the plasma is generated, and an exhaust space where a gas is exhausted from the interior of the chamber. The baffle plate is at least partially made of the material discussed above.

In an embodiment, the plasma processing apparatus further includes: a control unit configured to: (a) provide a substrate including a silicon-containing film and a mask on the silicon-containing film onto the substrate support unit; (b) supply the processing gas into the chamber through the gas supply port; and (c) etch the silicon-containing film by generating the plasma from the processing gas using the plasma generation unit.

In an embodiment, the mask is a carbon-containing film, a tungsten-containing film, a polysilicon-containing film, a ruthenium-containing film, a titanium nitride-containing film, a silicon boride-containing film, a samarium-containing film, or an yttrium-containing film.

In an embodiment, the gas supply port is connected to a source of a carbon-containing gas or a tungsten-containing gas, and the control unit is further configured to: (d) supply the carbon-containing gas or the tungsten-containing gas into the chamber to generate plasma after (c).

In an embodiment, all areas in the chamber exposed to the plasma are made of the material discussed above, and the mask contains the material discussed above.

In an embodiment, the plasma processing apparatus further includes: a sensor configured to measure a moisture concentration within the chamber.

In an embodiment, provided is a substrate processing system including: the above-described plasma processing apparatus; a transfer chamber; and a transfer apparatus configured to transfer a substrate from the transfer chamber into the chamber of the plasma processing apparatus. The transfer apparatus includes a sensor that measures a moisture concentration within the chamber.

In an embodiment, provided is a plasma processing apparatus including: a chamber; a substrate support unit provided within the chamber; a gas supply port connected to a source of a processing gas and configured to supply the processing gas into the chamber; a plasma generation unit configured to generate plasma containing HF species from the processing gas. The chamber is at least partially made of a material selected from carbon, tungsten, molybdenum, ruthenium, titanium nitride, samarium, and yttrium.

In an embodiment, the processing gas contains at least one gas selected from hydrogen fluoride gas, hydrofluorocarbon gas, hydrofluorocarbon gas having two or more carbon atoms, and a mixed gas of a hydrogen-containing gas and a fluorine-containing gas.

In an embodiment, the gas supply port is further connected to a source of a cleaning gas containing a hydrogen-containing gas. After performing a cycle that includes (a) to (c) one or more times, the control unit is further configured to: (e) supply the cleaning gas into the chamber; and (f) clean the interior of the chamber by generating plasma from the cleaning gas using the plasma generation unit.

In an embodiment, the hydrogen-containing gas is at least one of hydrogen gas and hydrocarbon gas.

In an embodiment, provided is a plasma processing apparatus including: a chamber; a substrate support unit provided within the chamber; a gas supply port connected to a source of a processing gas containing hydrogen fluoride gas, the gas supply port being configured to supply the processing gas into the chamber; a plasma generation unit configured to generate plasma from the processing gas; and a control unit. The control unit is configured to: (a) provide a substrate having a silicon-containing film and a mask on the silicon-containing film onto the substrate support unit; (b) supply the processing gas into the chamber through the gas supply port; and (c) etch the silicon-containing film by generating the plasma from the processing gas using the plasma generation unit. (a) to (c) are executed while at least a portion of parts within the chamber is made of a material containing at least one material selected from carbon, tungsten, molybdenum, ruthenium, titanium nitride, samarium, and yttrium.

In an embodiment, the gas supply port is further connected to a source of a precoat gas containing at least one material selected from carbon, tungsten, molybdenum, ruthenium, titanium nitride, samarium, and yttrium, and the control unit is further configured to form a precoat on at least a portion of the parts within the chamber with the precoat gas before (a).

In an embodiment, the precoat gas contains at least one material selected from hydrocarbon, halogenated tungsten, and halogenated molybdenum.

In an embodiment, the gas supply port is further connected to a source of a cleaning gas containing hydrogen. After performing a cycle that includes (a) to (c) once or more times, the control unit is further configured to: (e) supply the cleaning gas into the chamber; and (f) clean an interior of the chamber by generating plasma from the cleaning gas using the plasma generation unit.

Hereinafter, each embodiment of the present disclosure will be described in detail with reference to the drawings. In each drawing, the same or similar elements are denoted by the same reference numerals, and redundant descriptions will be omitted. Unless otherwise specified, positional relationships, such as upper, lower, left, and right, will be described based on the positional relationships illustrated in the drawings. The dimensional ratios in the drawings do not indicate the actual ratios, and the actual ratios are not limited to those illustrated in the drawings.

### <Configuration Example of Plasma Processing Apparatus>

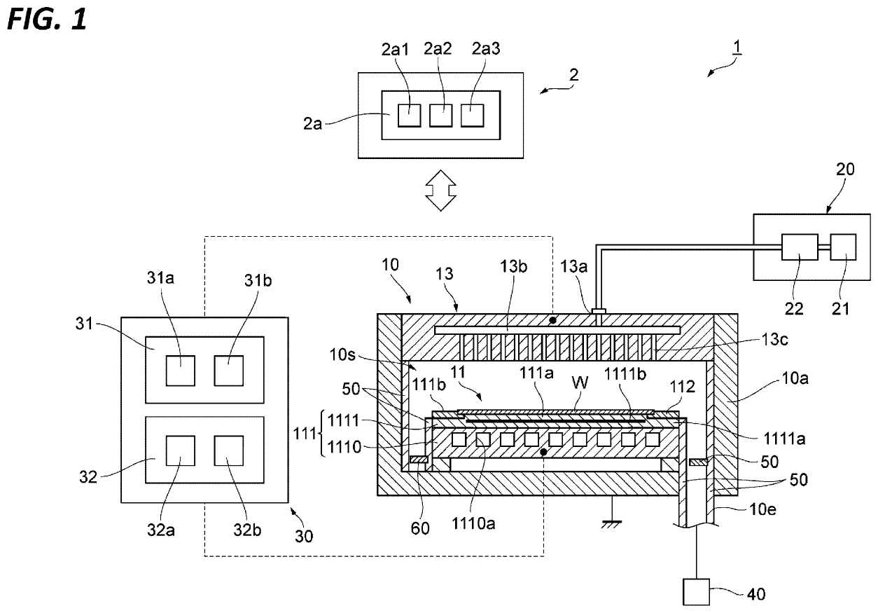

FIG. 1 is a view illustrating a configuration example of a capacitively coupled plasma processing apparatus 1. The capacitively coupled plasma processing apparatus 1 includes a control unit 2, a plasma processing chamber 10, a gas supply unit 20, a power supply 30, and an exhaust system 40. In addition, the plasma processing apparatus 1 includes a substrate support unit 11 and a gas introduction unit. The gas introduction unit is configured to introduce at least one processing gas into the plasma processing chamber 10. The gas introduction unit includes a showerhead 13. The substrate support unit 11 is disposed in the plasma processing chamber 10. The showerhead 13 is disposed above the substrate support unit 11. In an embodiment, the showerhead 13 constitutes at least a portion of the ceiling of the plasma processing chamber 10. The plasma processing chamber 10 has a plasma processing space 10s defined by the showerhead 13, the side wall 10a of the plasma processing chamber 10, and the substrate support unit 11. In addition, the plasma processing chamber 10 includes at least one gas supply port configured to supply at least one processing gas to the plasma processing space 10s, and at least one gas discharge port configured to discharge gas from the plasma processing space. The plasma processing chamber 10 is grounded. The showerhead 13 and the substrate support unit 11 are electrically insulated from the housing of the plasma processing chamber 10.

The substrate support unit 11 includes a main body 111 and a ring assembly 112. The main body 111 includes a central region 111a that supports a substrate W and an annular region 111b that supports the ring assembly 112. A wafer is an example of substrate W. The annular region 111b of the main body 111 surrounds the central region 111a of the main body 111 in a plan view. The substrate W is placed on the central region 111a of the main body 111, and the ring assembly 112 is disposed on the annular region 111b of the main body 111 to surround the substrate W on the central region 111a of the main body 111. Accordingly, the central region 111a is also referred to as a “substrate support surface” that supports the substrate W, and the annular region 111b is also referred to as a “ring support surface” that supports the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 111a. In an embodiment, the ceramic member 1111a also has an annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32, which will be described below, may be disposed inside the ceramic member 1111a. In this case, the at least one RF/DC electrode serves as a lower electrode. When a bias RF signal and/or a DC signal, which will be described below, is supplied to the at least one RF/DC electrode, the RF/DC electrode is also referred to as a “bias electrode.” In addition, the conductive member of the base 1110 and the at least one RF/DC electrode may function as a plurality of lower electrodes. Furthermore, the electrostatic electrode 1111b may function as a lower electrode. Accordingly, the substrate support unit 11 includes at least one lower electrode.

The ring assembly 112 includes one or more annular members. In an embodiment, the one or more annular members include one or more edge rings and at least one cover ring. The edge rings are made of a conductive material or an insulating material, and the cover ring is made of an insulating material.

In addition, the substrate support unit 11 may include a temperature regulating module configured to regulate at least one of the electrostatic chuck 1111, the ring assembly 112, and the substrate to a target temperature. The temperature regulating module may include a heater, a heat transfer medium, a flow path 1110a, or a combination thereof. A heat transfer fluid, such as brine or gas, flows through the flow path 1110a. In an embodiment, the flow path 1110a is formed inside the base 1110, and one or more heaters are disposed inside the ceramic member 1111a of electrostatic chuck 1111. In addition, the substrate support unit 11 may include a heat transfer gas supply unit that supplies a heat transfer gas to the gap between the rear surface of the substrate W and the central region 111a.

The showerhead 13 is configured to introduce at least one processing gas from the gas supply unit 20 into the plasma processing space 10s. The showerhead 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. In addition, the showerhead 13 includes at least one upper electrode. In addition to the showerhead 13, the gas introduction unit may include one or more side gas injectors (SGIs) installed in one or more openings formed in the side wall 10a.

The gas supply unit 20 may include one or more gas sources 21 and one or more flow rate controllers 22. In an embodiment, the gas supply unit 20 is configured to supply at least one processing gas from a corresponding one of the gas sources 21 to the showerhead 13 via a corresponding one of the flow rate controllers 22. Each flow rate controller 22 may include, for example, a mass flow controller or a pressure-controlled flow rate controller. In addition, the gas supply unit 20 may include one or more flow rate modulation devices configured to modulate or pulse the flow rate of at least one processing gas.

The power supply 30 includes an RF power supply 31 coupled to the plasma processing chamber 10 via at least one impedance matching circuit. The RF power supply 31 is configured to supply at least one RF signal (RF power) to the at least one lower electrode and/or the at least one upper electrode. As a result, plasma is generated from the at least one processing gas supplied into the plasma processing space 10s. Therefore, the RF power supply 31 may function as at least a portion of a plasma generation unit configured to generate plasma from one or more processing gases in the plasma processing chamber 10. In addition, by supplying a bias RF signal to the at least one lower electrode, a bias potential may be generated in the substrate W, and an ionic component in the formed plasma may be drawn into the substrate W.

In an embodiment, the RF power supply 31 includes a first RF generation unit 31a and a second RF generation unit 31b. The first RF generation unit 31a is coupled to the at least one lower electrode and/or the at least one upper electrode via at least one impedance matching circuit and configured to generate a source RF signal (source RF power) for plasma generation. In an embodiment, the source RF signal has a frequency within the range of 10 MHz to 150 MHz. In an embodiment, the first RF generation unit 31a may be configured to generate a plurality of source RF signals having different frequencies. One or more generated source RF signals are provided to the at least one lower electrode and/or the at least one upper electrode.

The second RF generation unit 31b is coupled to the at least one lower electrode via the at least one impedance matching circuit and configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency within the range of 100 kHz to 60 MHz. In an embodiment, the second RF generation unit 31b may be configured to generate a plurality of bias RF signals at different frequencies. One or more generated bias RF signals are provided to the at least one lower electrode. In addition, in various embodiments, at least one of the source RF signal and the bias RF signal may be pulsed. The power supply 30 may include a DC power supply 32 coupled to the plasma processing chamber 10. The DC power supply 32 includes a first DC generation unit 32a and a second DC generation unit 32b. In an embodiment, the first DC generation unit 32a is connected to the at least one lower electrode and configured to generate a first DC signal. The generated first DC signal is applied to the at least one lower electrode. In an embodiment, the second DC generation unit 32b is connected to the at least one upper electrode and configured to generate a second DC signal. The generated second DC signal is applied to the at least one upper electrode.

In various embodiments, at least one of the first and second DC signals may be pulsed. In this case, a sequence of voltage pulses is applied to the at least one lower electrode and/or the at least one upper electrode. The voltage pulses may have a rectangular pulse waveform, a trapezoidal pulse waveform, a triangular pulse waveform, or a combination thereof. In an embodiment, a waveform generation unit configured to generate a sequence of voltage pulses from a DC signal is connected between the first DC generation unit 32a and the at least one lower electrode. Therefore, the first DC generation unit 32a and the waveform generation unit constitute a voltage pulse generation unit. When the second DC generation unit 32b and the waveform generation unit constitute a voltage pulse generation unit, the voltage pulse generation unit is connected to at least one upper electrode. The voltage pulse may have a positive polarity or a negative polarity. In addition, the sequence of voltage pulses may include one or more positive voltage pulses and one or more negative voltage pulses within one cycle. The first and second DC generation units 32a and 32b may be provided in addition to the RF power supply 31, or the first DC generation unit 32a may be provided in place of the second RF generation unit 31b.

The exhaust system 40 may be connected to, for example, a gas discharge port 10e provided at the bottom of the plasma processing chamber 10. The exhaust system 40 may include a pressure regulating valve and a vacuum pump. By the pressure regulating valve, the pressure in the plasma processing space 10s is regulated. The vacuum pump may include a turbo molecular pump, a dry pump, or a combination thereof.

In an embodiment, the plasma processing chamber 10 may include a shield 50. The shield 50 may be detachably provided along the side wall 10a of the plasma processing chamber 10. The shield 50 defines a portion of the plasma processing space 10s. The shield 50 may suppress the adhesion of etching byproducts to the side wall 10a. In addition, the shield 50 may be detachably provided along the outer periphery of the substrate support unit 11.

In an embodiment, the plasma processing chamber 10 may include a baffle plate 60. The baffle plate 60 separates the interior of the plasma processing chamber 10 into the plasma processing space 10s and an exhaust space that includes a region near the gas discharge port 10e. The baffle plate 60 may suppress the infiltration of plasma into the exhaust space on the downstream side of the baffle plate 60. The baffle plate 60 may be provided near the bottom of the plasma processing chamber 10, between the substrate support unit 11 and the side wall 10a of the plasma processing chamber 10. The baffle plate 60 may be an annular plate. The baffle plate 60 may include openings such as through holes or slits for exhaust.

The control unit 2 processes computer-executable commands that cause the plasma processing apparatus 1 to execute various steps described herein. The control unit 2 may be configured to control each element of the plasma processing apparatus 1 to perform various steps described herein. In an embodiment, a part or all of the control unit 2 may be configured as a system outside the plasma processing apparatus 1. The control unit 2 may include a processor 2a1, a storage 2a2, and a communication interface 2a3. The control unit 2 is implemented by, for example, a computer 2a. The processor 2a1 may be configured to perform various control operations by reading a program from the storage 2a2 and executing the read program. This program may be stored in the storage 2a2 in advance, or may be acquired via a medium when necessary. The acquired program is stored in the storage 2a2, and is read from the storage 2a2 and executed by the processor 2a1. The medium may be various storage media readable by the computer 2a, or may be a communication line connected to the communication interface 2a3. The processor 2a1 may be a central processing unit (CPU). The storage 2a2 may include random access memory (RAM), read only memory (ROM), hard disk drive (HDD), solid state drive (SSD), or a combination thereof. The communication interface 2a3 may communicate with the plasma processing apparatus 1 via a communication line such as a local area network (LAN).

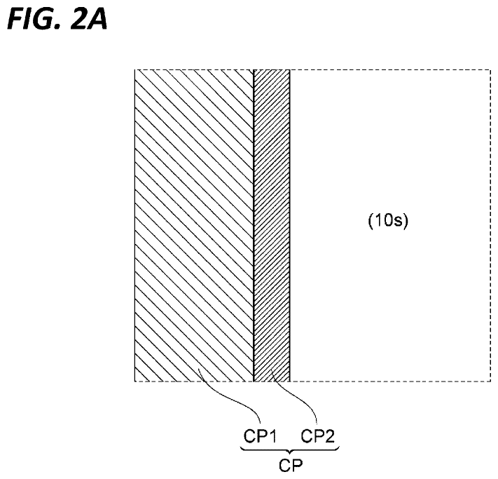

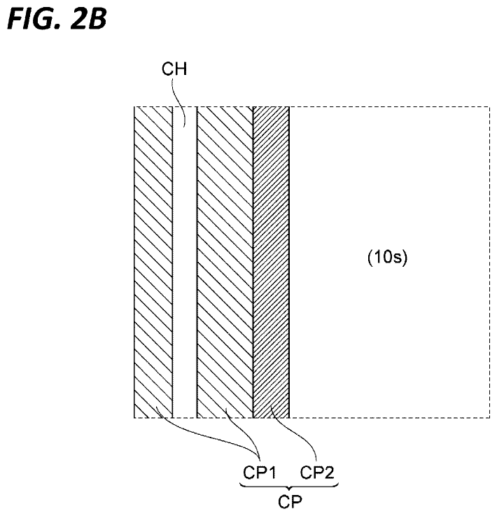

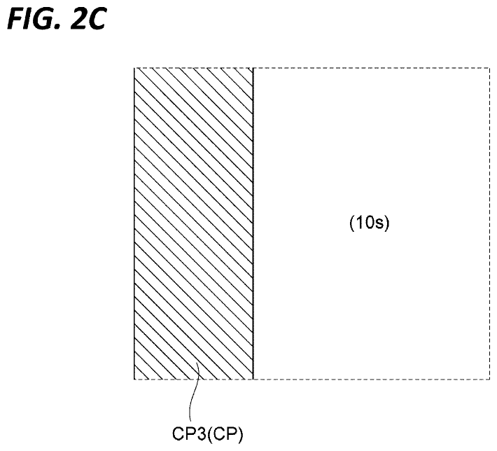

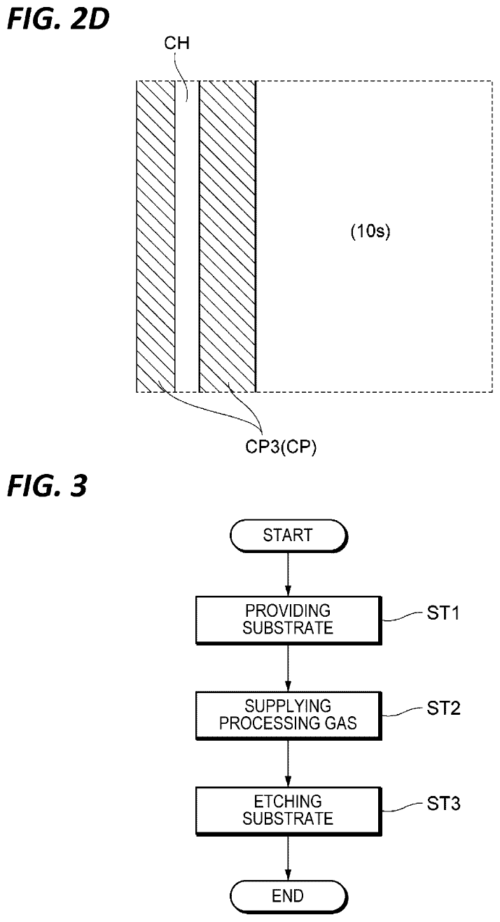

FIGS. 2A to 2D are views illustrating an example of the cross-sectional structure of a constituent member CP of the plasma processing chamber 10. The constituent member CP has a surface exposed to the plasma processing space 10s, i.e., a surface that is exposed to plasma (hereinafter referred to as a “plasma exposure surface”). In an example, the constituent member CP may be one or more the showerhead 13, the edge ring of the ring assembly 112, the side wall 10a, the shield 50, and the baffle plate 60, or a portion of such a component. In addition, in an example, the plasma exposure surface may be entirely formed by the constituent member CP.

As illustrated in FIG. 2A, the constituent member CP may include a first layer CP1 and a second layer CP2 on the first layer CP1. The first layer CP1 serves as the base material of the constituent member CP and may be appropriately selected depending on the type of the constituent member CP. For example, the first layer CP1 may be a silicon-containing material such as silicon or silicon carbide. Alternatively, the first layer CP1 may be a metallic material such as aluminum. The first layer CP1 may be fabricated by laminating a plurality of materials.

The second layer CP2 is the portion exposed to the plasma generated in the plasma processing space 10s. That is, the second layer CP2 has the plasma exposure surface. The second layer CP2 is made of a material M that includes at least one material selected from carbon, tungsten, molybdenum, ruthenium, titanium nitride, samarium, and yttrium. The material M may be, for example, a carbon-containing material or a tungsten-containing material. The carbon-containing material may be at least one material selected from diamond, graphite, diamond-like carbon, silicon carbide, tungsten carbide, and boron carbide. The tungsten-containing material may be at least one material selected from tungsten carbide (WC), tungsten silicide (WSi), tungsten oxide (WO), tungsten nitride (WN), tungsten silicon nitride (WSiN), and tungsten silicon carbide (WSiC).

The second layer CP2 may be formed as a coating on the first layer CP1. For example, the second layer CP2 may be formed by thermal spraying the material M onto the first layer CP1 or by chemically or physically depositing the material M onto the first layer CP1. That is, the second layer CP2 may be formed as a thermal spray film or a deposition film containing the material M. Alternatively, the second layer CP2 may be detachably configured as a liner (inner lining) that covers the first layer CP1.

FIG. 2B is a view illustrating an example in which the constituent member CP is configured to allow temperature regulation. As illustrated in FIG. 2B, a heat transfer channel CH may be formed in the first layer CP1 of the constituent member CP. A heat transfer fluid, such as brine or gas, flows through the heat transfer channel CH. By regulating the temperature of this heat transfer fluid, the temperature of the constituent member CP may be regulated to a given range. This may suppress the second layer CP2, which is exposed to plasma, from being damaged due to an excessive increase in temperature. The temperature of the heat transfer fluid may be appropriately set based on, for example, the material that forms the constituent member CP. When the constituent member CP is made of a silicon-containing material, the temperature of the heat transfer fluid may be set to, for example, 220° C. or lower.

The heat transfer channel CH may be provided externally rather than inside the first layer CP1 of the constituent member CP. The external heat transfer channel CH and the constituent member CP may be brought into direct thermal contact or indirect thermal contact via another member to regulate the temperature of the constituent member CP. The heat transfer channel CH may be shared by two or more components CP of the plasma processing chamber 10, or may be provided separately for each one or more components CP. For example, the showerhead 13 and the side wall 10a may be thermally connected to a single heat transfer channel CH through which the same heat transfer fluid flows, or may be thermally connected to two separate heat transfer channels CH, respectively, through which different heat transfer fluids flow.

FIG. 2C illustrates an example in which the constituent member CP itself is made of the material M. As illustrated in FIG. 2C, the constituent member CP may be configured as a third layer CP3 containing the material M. The third layer CP3 serves as the base material of the constituent member CP and has a plasma exposure surface.

FIG. 2D illustrates an example in which the third layer CP3 of FIG. 2C is configured to allow temperature regulation. As illustrated in FIG. 2D, the third layer CP3 of the constituent member CP may have the aforementioned heat transfer channel CH formed therein. This may suppress the third layer CP3, which is exposed to plasma, from being damaged due to an excessive increase in temperature. Alternatively, instead of providing the heat transfer channel CH inside the third layer CP3, the heat transfer channel CH may be provided outside the constituent member CP, and the constituent member CP and the external heat transfer channel CH may be brought into direct thermal contact or indirect thermal contact via another member to regulate the temperature of the constituent member CP.

### <Example of Plasma Processing Method>

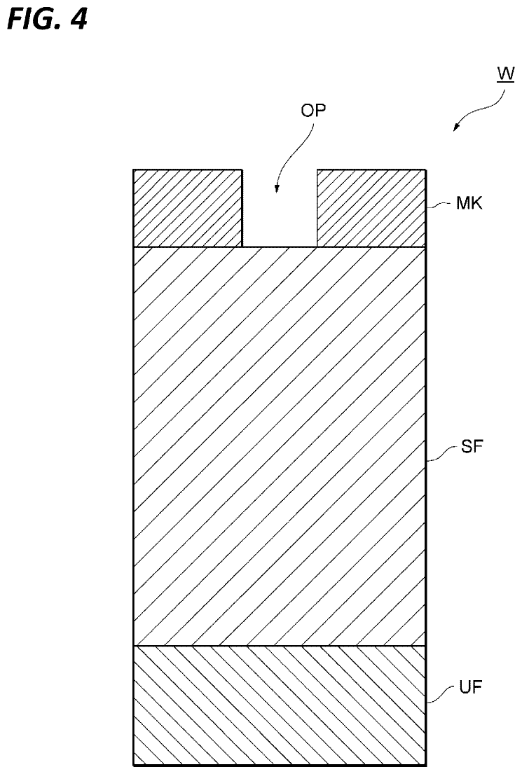

FIG. 3 is a flowchart illustrating an example of a plasma processing method (hereinafter referred to as “the present processing method”) performed by the plasma processing apparatus 1. As illustrated in FIG. 3, the present processing method includes: step ST1 of providing a substrate; step ST2 of supplying a processing gas; and step ST3 of etching the substrate. Below, an example is described in which the control unit 2 controls each component of the plasma processing apparatus 1 to execute the present processing method on a substrate W.

### (Step ST1: Providing Substrate)

In step ST1, the substrate W is provided in the plasma processing space 10s of the plasma processing apparatus 1. The substrate W is placed in the central area 111a of the substrate support unit 11. The substrate W is then held on the substrate support unit 11 by the electrostatic chuck 1111.

FIG. 4 is a view illustrating an example of the cross-sectional structure of the substrate W provided in step ST1. The substrate W includes a silicon-containing film SF and a mask MK formed on the silicon-containing film SF. The silicon-containing film SF may be formed on an underlying film UF. The substrate W may be used in the manufacture of semiconductor devices. The semiconductor devices include, for example, semiconductor memory devices such as DRAM and 3D-NAND flash memory.

In an example, the underlying film UF may be, for example, an organic film, a dielectric film, a metal film, or a semiconductor film formed on a silicon wafer or the silicon wafer itself. The underlying film UF may be formed by laminating a plurality of films.

The silicon-containing film SF is a film to be etched in the present processing method. The silicon-containing film SF may be, for example, a silicon oxide film, a silicon nitride film, a silicon oxynitride film, a silicon carbonitride film, a polysilicon film, or a carbon-containing silicon film. The silicon-containing film SF may be formed by laminating a plurality of films. For example, the silicon-containing film SF may be formed by alternately laminating silicon oxide films and silicon nitride films. For example, the silicon-containing film SF may be formed by alternately laminating silicon oxide films and polysilicon films. For example, the silicon-containing film SF may be a laminated film including silicon nitride films, silicon oxide films, and polysilicon films. For example, the silicon-containing film SF may be formed by laminating silicon oxide films and silicon carbonitride films. The silicon-containing film SF may be a laminated film including silicon oxide films, silicon nitride films, and silicon carbonitride films.

The mask MK is made of a material with a lower etching rate than the silicon-containing film SF when exposed to the plasma generated in step ST3. The mask MK may be made of, for example, a carbon-containing material. In an example, the mask MK may be an amorphous carbon film, a photoresist film, or a spin-on-carbon (SOC) film. The mask MK may also be a metal-containing film containing at least one metal selected from tungsten, molybdenum, titanium, ruthenium, samarium, and yttrium. In an example, the mask MK may contain tungsten carbide or tungsten silicide. In addition, the mask MK may contain tungsten and at least one material selected from silicon, carbon, and nitrogen. In an example, the mask MK may be at least one material selected from WSiN and WSiC. In an example, the mask MK may be titanium nitride (TiN). The mask MK may also be a silicon-containing film such as polysilicon or silicon boride. The mask MK may be a single-layer mask including a single or a multi-layer mask including two or more layers. In an embodiment, the mask MK may include the same material as the material M described above (i.e., the material forming part or all of the plasma exposure surface of the constituent member CP).

As illustrated in FIG. 4, the mask MK defines at least one opening OP on the silicon-containing film SF. The opening OP is a space on the silicon-containing film SF surrounded by a side wall of the mask MK. That is, the top surface of the silicon-containing film SF includes an area covered by the mask MK and an area exposed at the bottom of the opening OP.

The opening OP may have any shape when viewed in a plan view of the substrate W, i.e., when the substrate W is viewed in a direction from top to bottom in FIG. 4. The shape may be, for example, a circle, an ellipse, a rectangle, a line, or a combination of one or more of these shapes. The mask MK may have a plurality of side walls, and these side walls may define a plurality of openings OP. The openings OP may have linear shapes and may be arranged at regular intervals to form a line-and-space pattern. Alternatively, the openings OP may have hole shapes, respectively, and may form an array pattern.

Each film forming the substrate W (the underlying film UF, the silicon-containing film SF, or the mask MK) may be formed through, for example, CVD, ALD, or spin coating. The mask MK may be formed through lithography. In addition, the openings OP of the mask MK may be formed by etching the mask MK. Each film may be flat or have a rough surface. In addition, the substrate W may include other films beneath the underlying film UF. In this case, recesses corresponding to the shape of the openings OP may be formed in the silicon-containing film SF and the underlying film UF, and the other films may be used as an etching mask.

At least some of the processes for forming the respective films of the substrate W may be performed within the space of the plasma processing chamber 10. In an example, the step of etching the mask MK to form an opening OP may be performed in the plasma processing chamber 10. That is, the opening OP and the subsequent etching of the silicon-containing film SF may be performed sequentially within the same chamber. Alternatively, after all or part of each film of the substrate W is formed in an apparatus or chamber outside the plasma processing apparatus 1, the substrate W may be provided by being transported into the plasma processing space 10s of the plasma processing apparatus 1 and disposed in the central area 111a of the substrate support unit 11.

After providing the substrate W to the central area 111a of the substrate support unit 11, the temperature of the substrate support unit 11 is regulated to a set temperature by a temperature regulating module. The set temperature may be, for example, 0° C. or lower, −10° C. or lower, −20° C. or lower, −30° C. or lower, −40° C. or lower, −50° C. or lower, −60° C. or lower, or −70° C. or lower. In an example, regulating or maintaining the temperature of the substrate support unit 11 may including setting the temperature of the heat transfer fluid flowing through the flow path 1110a or the heater temperature to the set temperature, or to a temperature different from the set temperature. The timing of starting the flow of the heat transfer fluid through the flow path 1110a may be before, after, or at the same time as the disposition of the substrate W on the substrate support unit 11. The temperature of the substrate support 11 may be regulated to the set temperature before step ST11. That is, the substrate W may be provided to the substrate support unit 11 after the temperature of the substrate support unit 11 is regulated to the set temperature.

### (Step ST2: Supplying Processing Gas)

In step ST2, a processing gas containing hydrogen fluoride (HF) gas is supplied from the gas supply unit 20 into the plasma processing space 10s. During the process in step ST3, which will be described later, the gases contained in the processing gas and flow rates (partial pressures) thereof may or may not be changed. For example, when the silicon-containing film SF is formed as a laminated film made of different types of silicon-containing films, the composition of the processing gas and the flow rate (partial pressure) of each gas may be changed depending on the progress of etching (i.e., depending on the type of film being etched). During the processing in step ST2, the temperature of the substrate support unit 11 may be maintained at the set temperature regulated in step ST1 or may be changed.

In step ST2, the HF gas contained in the processing gas may have the highest flow rate (partial pressure) among the gases in the processing gas (excluding inert gases, if any). In an example, the flow rate of HF gas may be 50 volume % or more, 60 volume % or more, 70 volume % or more, 80 volume % or more, 90 volume % or more, or 95 volume % or more of the total flow rate of the processing gas (excluding inert gases, if any). The flow rate of HF gas may be less than 100 volume %, 99.5 volume % or less, 98 volume % or less, or 96 volume % or less of the total flow rate of the processing gas. In an example, the flow rate of HF gas may be regulated to 70 volume % or more and 96 volume % or less of the total flow rate of the processing gas.

The processing gas may further contain a phosphorus-containing gas. The phosphorus-containing gas is a gas that contains phosphorus-containing molecules. The phosphorus-containing molecules may be oxides such as tetraphosphorus decaoxide (P₄O₁₀), tetraphosphorus octaoxide (P₄O₈), or tetraphosphorus hexaoxide (P₄O₆). The tetraphosphorus decaoxide may also be referred to as diphosphorus pentoxide (P₂O₅). The phosphorus-containing molecules may also be halides such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), or phosphorus triiodide (PI₃). That is, the phosphorus-containing molecules may include fluorinated phosphorus, which contains fluorine as the halogen element. Alternatively, the phosphorus-containing molecules may contain halogen elements other than fluorine. The phosphorus-containing molecules may also be phosphoryl halides such as phosphoryl fluoride (POF₃), phosphoryl chloride (POCl₃), or phosphoryl bromide (POBr₃). In addition, the phosphorus-containing molecules may be phosphine (PH₃), calcium phosphide (Ca₃P₂), phosphoric acid (H₃PO₄), sodium phosphate (Na₃PO₄), or hexafluorophosphoric acid (HPF₆). The phosphorus-containing molecules may also be fluoro-phosphines (H_{g}PFₕ). Here, the sum of g and h is 3 or 5. Examples of fluorophosphines include HPF₂ and H₂PF₃. The processing gas may contain one or more phosphorus-containing molecules selected from the above phosphorus-containing molecules. For example, the processing gas may contain at least one phosphorus-containing molecule selected from PF₃, PCl₃, PF₅, PCl₅, POCl₃, PH₃, PBr₃, or PBr₅. When each phosphorus-containing molecule contained in the processing gas is liquid or solid, each phosphorus-containing molecule may be vaporized by heating or the like and then supplied into the plasma processing space 10s.

The phosphorus-containing gas may be a gas such as PClₐF_{b} (where a is an integer of 1 or more, b is an integer of 0 or more, and a+b is an integer of 5 or less) or PC_{c}H_{d}Fₑ (where d and e are integers of 1 to 5, and c is an integer of 0 to 9).

The PClₐF_{b} gas may include, for example, at least one gas selected from PClF₂ gas, PCl₂F gas, and PCl₂F₃ gas.

The PCcHdFe gas may include, for example, at least one gas selected from PF₂CH₃ gas, PF(CH₃)₂ gas, PH₂CF₃ gas, PH(CF₃)₂ gas, PCH₃(CF₃)₂ gas, PH₂F gas, and PF₃(CH₃)₂ gas.

The phosphorus-containing gas may also be a gas such as PCl_{c}F_{d}CₑH_{f} (where c, d, e, and f are each integers of 1 or more). In addition, the phosphorus-containing gas may be a gas containing phosphorus (P), fluorine (F), and halogens other than F (fluorine) (e.g., Cl, Br, or I) in its molecular structure, a gas containing phosphorus (P), fluorine (F), carbon (C), and hydrogen (H) in its molecular structure, or a gas containing phosphorus (P), fluorine (F), and hydrogen (H) in its molecular structure.

A phosphine-based gas may be used as the phosphorus-containing gas. Examples of the phosphine-based gases include phosphine (PH₃), compounds in which at least one hydrogen atom of phosphine is substituted with an appropriate substituent, and phosphine acid derivatives.

The substituents replacing hydrogen atoms of phosphine are not particularly limited and may include, for example, halogen atoms such as fluorine and chlorine atoms; alkyl groups such as methyl, ethyl, and propyl groups; and hydroxyalkyl groups such as hydroxymethyl, hydroxyethyl, and hydroxypropyl groups. Examples include chlorine atoms, methyl groups, and hydroxymethyl groups.

Examples of phosphinic acid derivatives may include phosphinic acid (H₃O₂P), alkyl phosphinic acid (PHO(OH) R), and dialkyl phosphinic acid (PO(OH)R₂).

As the phosphine-based gas, at least one selected from, for example, PCH₃Cl₂ (dichloro(methyl)phosphine) gas, P(CH₃)₂Cl (chloro(dimethyl) phosphine) gas, P(HOCH₂)Cl₂ (dichloro(hydroxymethyl) phosphine) gas, P(HOCH₂)₂Cl (chloro(dihydroxymethyl)phosphine) gas, P(HOCH₂)(CH₃)₂ (dimethyl(hydroxymethyl)phosphine) gas, P(HOCH₂)₂(CH₃) (methyl(dihydroxymethyl)phosphine) gas, P(HOCH₂)₃ (tris(hydroxymethyl) phosphine) gas, H₃O₂P (phosphinic acid) gas, PHO(OH) (CH₃) (methyl phosphinic acid) gas, and PO(OH)(CH₃)₂ (dimethyl phosphinic acid) gas, may be used.

The flow rate of the phosphorus-containing gas in the processing gas may be 20 volume % or less, 10 volume % or less, or 5 volume % or less of the total flow rate of the processing gas.

The processing gas may further contain a tungsten-containing gas. The tungsten-containing gas may be a gas containing tungsten and halogen, such as WFₓCl_{y} gas (where x and y are each an integer 0 or more and 6 or less, and the sum of x and y is 2 or more and 6 or less). Specifically the tungsten-containing gas may be a gas containing tungsten and fluorine, such as tungsten difluoride (WF₂) gas, tungsten tetrafluoride (WF₄) gas, tungsten pentafluoride (WF₅) gas, or tungsten hexafluoride (WF₆) gas, as well as a gas containing tungsten and chlorine such as tungsten dichloride (WCl₂) gas, tungsten tetrachloride (WCl₄) gas, tungsten pentachloride (WCl₅) gas, and tungsten hexachloride (WCl₆) gas. Among these, the tungsten-containing gas may be at least one of WF₆ gas and WCl₆ gas. The flow rate of the tungsten-containing gas may be 5 volume % or less of the total flow rate of the processing gas. In addition, the processing gas may contain one or more of titanium-containing gas, molybdenum-containing gas, and ruthenium-containing gas instead of or in addition to the tungsten-containing gas.

The processing gas may further contain a carbon-containing gas. The carbon-containing gas may be, for example, one or both of fluorocarbon gas and hydrofluorocarbon gas. In an example, the fluorocarbon gas may be at least one gas selected from CF₄ gas, C₂F₂ gas, C₂F₄ gas, C₃F₆ gas, C₃F₈ gas, C₄F₆ gas, C₄F₈ gas, and C₅F₈ gas. In an example, the hydrofluorocarbon gas may be at least one gas selected from CHF₃ gas, CH₂F₂ gas, CH₃F gas, C₂HF₅ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, CH₂F₆ gas, C₅H₂F₁₀ gas, and C₅H₃F₇ gas. In addition, the carbon-containing gas may be a linear carbon-containing gas having unsaturated bonds. The linear carbon-containing gas having unsaturated bonds may be at least one selected from, for example, C₃F₆ (hexafluoropropene) gas, C₄F₈ (octafluoro-1-butene or octafluoro-2-butene) gas, C₃H₂F₄ (1,3,3,3-tetrafluoropropene) gas, C₄H₂F₆ (trans-1,1,1,4,4,4-hexafluoro-2-butene) gas, C₄F₈O (pentafluoroethyl trifluorovinyl ether) gas, CF₃COF (1,2,2,2-tetrafluoroethan-1-one) gas, CHF₂COF (difluoroacetic fluoride) gas, and COF₂ (carbonyl fluoride) gas.

The processing gas may further include an oxygen-containing gas. The oxygen-containing gas may be at least one selected from O₂, CO, CO₂, H₂O, and H₂O₂. In an example, the oxygen-containing gas may be at least one gas selected from oxygen-containing gases other than H₂O, such as O₂, CO, CO₂, and H₂O₂. The flow rate of the oxygen-containing gas may be regulated based on the flow rate of the carbon-containing gas.

The processing gas may further include a halogen-containing gas other than fluorine. The halogen-containing gas other than fluorine may be a chlorine-containing gas, a bromine-containing gas, and/or an iodine-containing gas. In an example, the chlorine-containing gas may be at least one selected from Cl₂, SiCl₂, SiCl₄, CCl₄, SiH₂Cl₂, Si₂Cl₆, CHCl₃, SO₂Cl₂, BCl₃, PCl₃, PCl₅, and POCl₃. The bromine-containing gas may be at least one selected from Br₂, HBr, CBr₂F₂, C₂F₅Br, PBr₃, PBr₅, POBr₃, and BBr₃. The iodine-containing gas may be at least one selected from HI, CF₃I, C₂F₅I, C₃F₇I, IF₅, IF₇, I₂, and PI₃. In an example, the halogen-containing gas other than fluorine may be at least one gas selected from Cl₂ gas, Br₂ gas, and HBr gas. In an example, the halogen-containing gas may be Cl₂ gas or HBr gas.

The processing gas may further include an inert gas. In an example, the inert gas may be a noble gas such as Ar gas, He gas, or Kr gas, or nitrogen gas.

The processing gas may contain a gas capable of generating hydrogen fluoride species (HF species) in the plasma instead of or in addition to part or all of the HF gas. The HF species may include at least one of hydrogen fluoride gas, radicals, and ions.

The gas capable of generating HF species may be, for example, a hydrofluorocarbon gas. The hydrofluorocarbon gas may have two or more, three or more, or four or more carbon atoms. In an example, the hydrofluorocarbon gas is at least one gas selected from CH₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. In an example, the hydrofluorocarbon gas may be at least one gas selected from CH₂F₂ gas, C₃H₂F₄ gas, C₃H₂F₆ gas, and C₄H₂F₆ gas.

The gas capable of generating HF species may be, for example, a mixed gas containing a hydrogen source and a fluorine source. The hydrogen source may be at least one gas selected from H₂ gas, NH₃ gas, H₂O gas, H₂O₂ gas, and hydrocarbon gases (such as CH₄ gas and C₃H₆ gas). The fluorine source may be, for example, a fluorine-containing gas that does not contain carbon, such as NF₃ gas, SF₆ gas, WF₆ gas, or XeF₂ gas. In addition, the fluorine source may be a fluorine-containing gas that contains carbon, such as a fluorocarbon gas or a hydrofluorocarbon gas. In an example, the fluorocarbon gas may be at least one gas selected from CF₄ gas, C₂F₂ gas, C₂F₄ gas, C₃F₆ gas, C₃F₈ gas, C₄F₆ gas, C₄F₈ gas, and C₅F₈ gas. In an example, the hydrofluorocarbon gas may be at least one gas selected from CHF₃ gas, CH₂F₂ gas, CH₃F gas, C₂HF₅ gas, and hydrofluorocarbon gases containing three or more carbon atoms (such as C₃HF₄, C₃H₂F₆, and C₄H₂F₆).

### (Step ST3: Etching Substrate)

In step ST3, the substrate W is etched. First, a source RF signal is supplied to the lower electrode of the substrate support unit 11 and/or the upper electrode of the showerhead 13. As a result, a radio-frequency electric field is generated between the showerhead 13 and the substrate support unit 11, and plasma is generated from the processing gas within the plasma processing space 10s. During the processing in step ST3, the temperature of the substrate support unit 11 may be maintained at the set temperature regulated in step ST1 or may be changed.

In step ST3, a bias signal may be supplied to the lower electrode of the substrate support unit 11. In this case, a bias potential may be generated between the plasma and the substrate W, and active species such as ions and radicals in the plasma may be attracted to the substrate W, thereby promoting the etching of the silicon-containing film SF. The bias signal may be a bias RF signal supplied from the second RF generation unit 31b. In addition, the bias signal may be a bias DC signal supplied from the DC generation unit 32a.

The source RF signal and the bias signal may both be continuous waves or pulse waves, or one may be a continuous wave while the other is a pulse wave. When both the source RF signal and the bias signal are pulse waves, the cycles of the two pulse waves may be synchronized or unsynchronized. The duty ratio of the source RF signal and/or the bias signal pulse wave may be set as appropriate, for example, between 1% and 80%, or between 5% and 50%. The duty ratio represents the proportion of the period during which the power or voltage level is high in the pulse wave cycle. When a bias DC signal is used as the bias signal, the pulse wave may have a rectangular waveform, trapezoidal waveform, triangular waveform, or a combination of these waveforms. The polarity of the bias DC signal may be negative or positive, provided that the potential of the substrate W is set to provide a potential difference between the plasma and the substrate to draw ions into the substrate.

In step ST3, the supply and stop of at least one of the source RF signal and the bias signal may be alternately repeated. For example, while the source RF signal is continuously supplied, the supply and stop of the bias signal may be alternately repeated. For example, while the supply and stop of the source RF signal are alternately repeated, the bias signal may be continuously supplied. For example, the supply and stop of both the source RF signal and the bias signal may be alternately repeated.

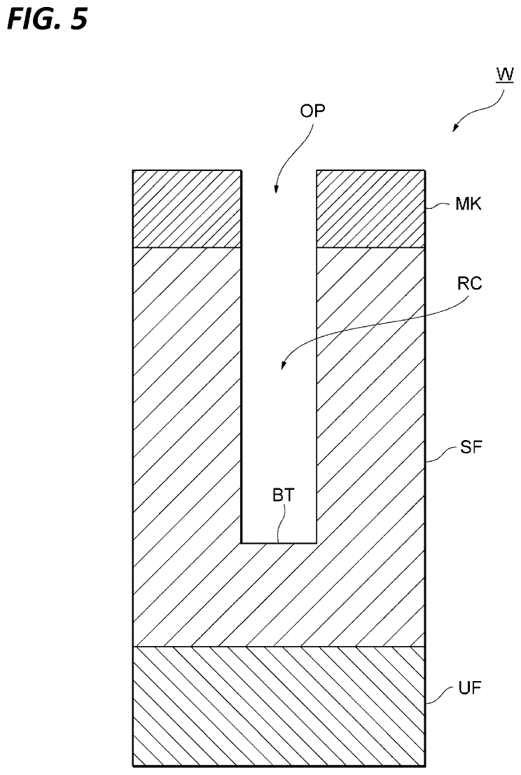

FIG. 5 is a view illustrating an example of the cross-sectional structure of the substrate W during the processing of step ST3. As illustrated in FIG. 5, the HF species (etchant) in the plasma etches a portion of the silicon-containing film SF that is not covered by the mask MK (i.e., the portion exposed in an opening OP) in the depth direction. This forms a recess RC in the silicon-containing film SF based on the shape of the opening OP of the mask MK.

When a given stop condition is met, the etching in step ST3 is stopped, and the present processing method is completed. The stop condition may be, for example, the etching time or the depth of the recess RC. The aspect ratio of the recess RC at the end of etching may be, for example, 20 or more, and may also be 30 or more, 40 or more, 50 or more, or 100 or more.

As described above, in the plasma processing apparatus 1, the plasma exposure surface of the constituent member CP in the plasma processing chamber 10 is formed of the material M. The carbon, tungsten, and/or molybdenum in the material M exhibit low reactivity with the HF species in the plasma generated in step ST3. Thus, during the etching in step ST3, the reaction and consumption of the HF species in the plasma at the plasma exposure surface of the constituent member CP are suppressed. This may make it possible to provide a greater amount of HF species (etchant for the silicon-containing film SF) in the plasma to the substrate W, thereby increasing the etching rate of the silicon-containing film SF. In addition, the HF species in the plasma are suppressed from reacting with the plasma exposure surface of the constituent member CP, and from damaging the exposure surface.

### Example

Next, an example in which the present processing method was executed using the plasma processing apparatus 1 will be described. The present disclosure is not limited by the following example in any way.

The plasma processing apparatus according to Example 1 had the showerhead 13 with the configuration illustrated in FIG. 2A, in the plasma processing apparatus 1 illustrated in FIG. 1. Specifically, the showerhead 13 of the plasma processing apparatus in Example 1 was composed of a base material (first layer CP1) made of aluminum and a tungsten film (second layer CP2) thermally sprayed onto the base material. The thickness of the base material was 4.8 mm, and the thickness of the tungsten film was 0.2 mm.

The plasma processing apparatus according to Reference Example 1 was the same as Example 1, except that the showerhead was composed of a base material made of silicon. The thickness of the base material was 5 mm.

The plasma processing apparatus according to Reference Example 2 was the same as Example 1, except that the showerhead was composed of a base material made of aluminum and a silicon film thermally sprayed onto the base material. The thickness of the base material was 4.8 mm, and the thickness of the silicon film was 0.2 mm.

The plasma processing apparatus according to Reference Example 3 was the same as Example 1, except that the showerhead was composed of a base material made of aluminum and an yttria film thermally sprayed onto the base material. The thickness of the base material was 4.8 mm, and the thickness of the yttria film was 0.2 mm.

Using the plasma processing apparatuses of Example 1 and Reference Examples 1 through 3, a substrate similar to the substrate W illustrated in FIG. 4 was etched according to the flowchart described with reference to FIG. 3. The mask MK of the substrate W was an amorphous carbon film, and the silicon-containing film SF was a laminated film of silicon oxide and silicon nitride. The processing gas contained hydrogen fluoride gas and a phosphorus-containing gas. During the etching, the temperature of the substrate support unit 11 was set to −70° C. For each of Example 1 and Reference Examples 1 to 3, the etching rate was measured when the flow rate of hydrogen fluoride gas was set to 100, 250, 500, and 650 sccm. The time-dependent changes in the composition of the plasma in the plasma processing space were also measured using a quadrupole mass analyzer.

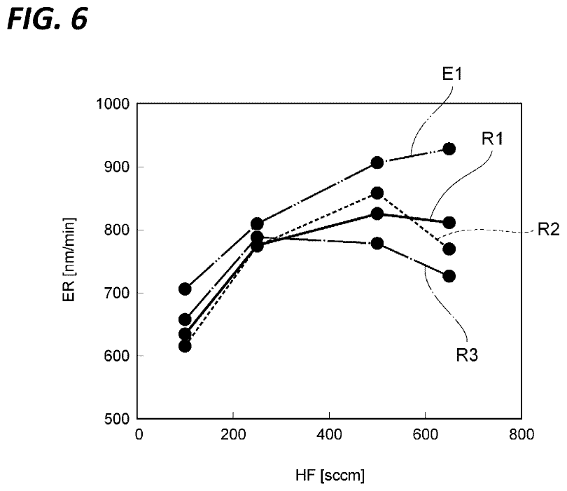

FIG. 6 is a diagram illustrating the relationship between the flow rate of hydrogen fluoride gas and the etching rate. In FIG. 6, the horizontal axis represents the flow rate of hydrogen fluoride gas in the processing gas (HF [sccm]). The vertical axis represents the etching rate of a silicon-containing film SF (EF [nm/min]). “E1,” “R1,” “R2,” and “R3” represent the results obtained when using the plasma processing apparatuses of Example 1, Reference Example 1, Reference Example 2, and Reference Example 3, respectively. As illustrated in FIG. 6, regardless of whether the flow rate of hydrogen fluoride gas was 100, 250, 500, or 650 sccm, the plasma processing apparatus of Example 1 exhibited the highest etching rate. In the case where the plasma processing apparatuses of Reference Examples 1 to 3 were used, the etching rate tended to decrease when the flow rate of hydrogen fluoride gas was increased, but such a tendency was not observed in Example 1. That is, in the case where the plasma processing apparatus of Example 1 was used, the etching rate was also increased when the flow rate of hydrogen fluoride gas was increased. This is believed to be because, in Example 1, the consumption of HF species in the plasma due to reactions at the showerhead was suppressed compared to Reference Examples 1 through 3, and as a result, a greater amount of HF species (etchant) was supplied to the substrate.

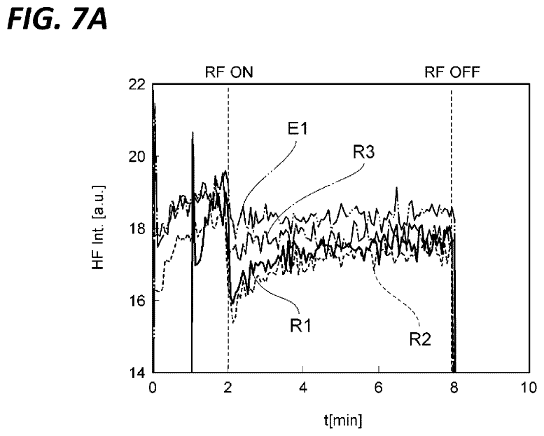

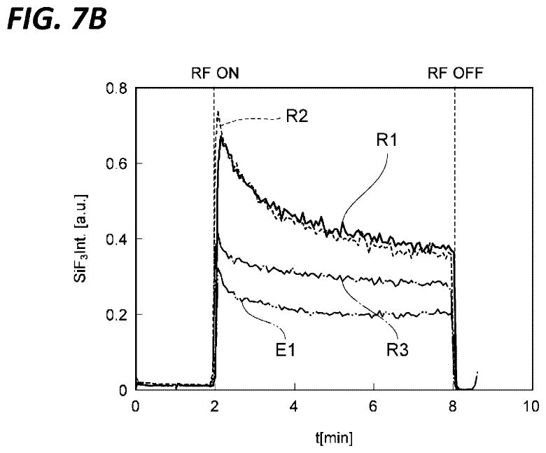

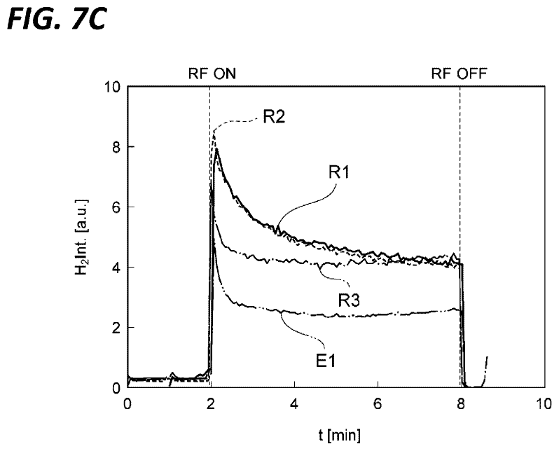

FIG. 7A illustrates the time-dependent changes in hydrogen fluoride (HF) intensity within the plasma processing space. FIG. 7B illustrates the time-dependent changes in silicon trifluoride (SiF₃) intensity within the plasma processing space. FIG. 7C illustrates the time-dependent changes in hydrogen (H₂) intensity within the plasma processing space. FIGS. 7A to 7C show the results obtained when the flow rates of hydrogen fluoride gas were 500 sccm.

In FIGS. 7A to 7C, the vertical axes represent the intensities of hydrogen fluoride, silicon trifluoride, and hydrogen, respectively, while the horizontal axes represent time. “RF ON” indicates the timing when step ST3 was initiated, and “RF OFF” indicates the timing when step ST3 was terminated. That is, plasma was generated during the period between “RF ON” and “RF OFF.” “E1,” “R1,” “R2,” and “R3” represent the results obtained when using the plasma processing apparatuses of Example 1, Reference Example 1, Reference Example 2, and Reference Example 3, respectively.

As illustrated in FIG. 7A, in the case where the plasma processing apparatus of Example 1 was used during step ST3, the HF intensity was higher compared to those of Reference Examples 1 to 3. This is believed to be because, in Example 1, the consumption of HF species in the plasma due to reactions at the showerhead was suppressed compared to Reference Examples 1 through 3. As illustrated in FIGS. 7B and 7C, in the case where the plasma processing apparatus of Example 1 was used, the SiF₃ and H₂ intensities were lower compared to those of Reference Examples 1 to 3. The reason why the intensities of SiF₃ and H₂ are particularly high in Reference Examples 1 and 2 is believed to be that the plasma exposure surface of the showerhead in Reference Examples 1 and 2 was composed of silicon. In Reference Examples 1 and 2, it is believed that the HF species reacted with silicon at the plasma exposure surface of the showerhead, generating SiF₃ and H₂ as reaction byproducts.

### <Modification>

Next, a modification will be described. The present disclosure is not limited by the following modification in any way.

In an embodiment, the present processing method may include, after step ST3, step ST4 of supplying a processing gas containing the aforementioned carbon-containing gas or tungsten-containing gas into the chamber, and step ST5 of generating plasma from the processing gas. This may cause the carbon or tungsten in the plasma to adhere to the plasma exposure surface of the constituent member CP in the plasma processing chamber 10 and form a protective film. This protective film may suppress the reaction of the constituent member CP with the HF species in the plasma during the etching in step ST3. When processing a plurality of substrates W as a single unit (lot), steps ST4 and ST5 may be performed after performing steps ST1 to ST3 for one or more substrates W in the lot.

In an embodiment, the plasma processing apparatus 1 may include a sensor configured to measure the moisture concentration in the plasma processing space 10s. In the present processing method, step ST6 of measuring the moisture concentration in the plasma processing space 10s using the sensor may be further performed after step ST3. When the moisture concentration is equal to or greater than a given value, step ST7 of reducing the moisture concentration in the plasma processing space 10s may be further performed after step ST6. Step ST7 may be performed, for example, by supplying, for example, an inert gas, into the plasma processing space 10s to purge the excess moisture from the space. By suppressing the moisture within the plasma processing space 10s, it may be possible to suppress the reaction between the HF species in the plasma and the plasma exposure surface of the constituent member CP during step ST3 from being promoted. When processing a plurality of substrates W as a lot, steps ST6 and ST7 may be performed after performing steps ST1 to ST3 for one or more substrates W in the lot.

In an embodiment, the plasma processing apparatus 1 may be connected to a supply source of cleaning gas. For example, at least one of the gas sources 21 in the gas supply unit 20 may be a cleaning gas containing hydrogen gas. The cleaning gas may be introduced into the plasma processing space 10s from the gas supply unit 20 through the showerhead 13. In an embodiment, the present processing method may further perform, after step ST3, step ST8 of supplying a cleaning gas containing hydrogen gas into the plasma processing space 10s, and step ST9 of generating plasma from the cleaning gas. When processing a plurality of substrates W as a single unit (lot), steps ST8 and ST9 may be executed after performing steps ST1 to ST3 for one or more substrates W in the lot. That is, after executing a cycle that includes steps ST1 through ST3 one or more times, steps ST8 and ST9 may be executed.

In step ST9, the plasma generated from the cleaning gas containing hydrogen gas may clean the interior of the plasma processing chamber 10. Specifically, the reactive species of hydrogen in the plasma may remove the reaction byproducts having adhered to the constituent member CP in the plasma processing chamber 10. For example, when the processing gas in step ST2 includes a phosphorus-containing gas, the reaction byproducts may include phosphorus compounds. These phosphorus compounds may react with the reactive species of hydrogen in the plasma during step ST9 and volatilize as phosphine (PH₃) gas.

In an embodiment, the hydrogen-containing gas contained in the cleaning gas may contain at least one gas selected from hydrogen gas, hydrocarbon gas, and hydrofluorocarbon gas. In an embodiment, the hydrogen-containing gas may be a gas that does not contain fluorine. For example, the hydrogen-containing gas may be at least one of hydrogen (H₂) gas and hydrocarbon gas (e.g., CH₄ gas or C₃H₆ gas). When the cleaning gas does not contain fluorine, in step ST9, the material M of the second layer CP2 of the constituent member CP may be suppressed from reacting with the reactive species of fluorine in the plasma. That is, the consumption of the constituent member CP during cleaning may be suppressed.

In an embodiment, steps ST1 to ST3 may be executed while at least a portion of the constituent member CP in the plasma processing chamber 10 is made of a material containing at least one material selected from carbon, tungsten, molybdenum, ruthenium, titanium nitride, samarium, and yttrium. In an embodiment, the plasma processing apparatus 1 may be connected to a supply source of precoat gas. For example, at least one of the gas sources 21 in the gas supply unit 20 may be a precoat gas. The precoat gas may be introduced into the plasma processing space 10s from the gas supply unit 20 through the showerhead 13.

In an embodiment, the present processing method may include step ST0 of introducing a precoat gas into the plasma processing space 10s before step ST1. In step ST0, plasma may be generated from the precoat gas. In an embodiment, the precoat gas may contain at least one material selected from carbon, tungsten, molybdenum, ruthenium, titanium nitride, samarium, and yttrium. As a result, a precoat containing carbon, tungsten, molybdenum, ruthenium, titanium nitride, samarium, and/or yttrium may be formed on the plasma exposure surface of the constituent member CP in the plasma processing chamber 10. This precoat may suppress the reaction of the constituent member CP with HF species in the plasma during the etching in step ST3.

In an embodiment, the precoat gas may include the aforementioned carbon-containing gas or the aforementioned tungsten-containing gas.

In an embodiment, the present processing method may execute, after executing a cycle that includes steps ST0 to ST3 one or more times, one or more of the aforementioned protective film formation steps (steps ST4 and ST5), the moisture concentration measurement and reduction steps (steps ST6 and ST7), and the cleaning steps (steps ST8 and ST9).

In an embodiment, the constituent member CP may be formed by thermally spraying the material M onto the surface of another member, or by performing chemical vapor deposition or physical vapor deposition of the material M onto the surface of another member. Alternatively, the constituent member CP may be formed by laminating the material M onto the surface of another member using, for example, a 3D printer. For example, the showerhead 13 may be formed by thermally spraying the material M directly onto a cooling plate that has a heat transfer channel CH inside.

Typically, the showerhead 13 is fixed to the cooling plate, which has a heat transfer channel, by clamping its periphery with a clamping member. In such a structure (hereinafter referred to as a “CEL structure”), the showerhead 13 is cooled by a heat transfer fluid such as a coolant flowing through the heat transfer channel. On the other hand, in the CEL structure, a microscopic gap may occur between the showerhead 13 and the cooling plate. In such a case, the heat transfer between the showerhead 13 and the cooling plate is hindered. When the showerhead 13 undergoes thermal expansion due to heat input from the plasma, compressive stress is generated in the showerhead 13. As a result, the gap between the showerhead 13 and the cooling plate increases, causing an increase in compressive force in the showerhead 13, which may eventually lead to the failure of the showerhead 13.

For this CEL structure, when the showerhead 13 is formed by thermally spraying the material M directly onto the cooling plate, the cooling plate and the showerhead 13 may be brought into close contact to reduce the gap therebetween. Accordingly, this structure improves the thermal conductivity between the cooling plate and the showerhead 13. In an example, this structure suppresses the temperature rise of the showerhead 13 during the process by 100° C. or more, or 150° C. or more, compared to the CEL structure. Accordingly, this structure may suppress the failure of the showerhead 13 caused by its thermal expansion.

In this embodiment, in addition to at least one material selected from the aforementioned carbon, tungsten, molybdenum, ruthenium, titanium nitride, and samarium, a plasma-resistant material may also be used as the material M. As the plasma-resistant material, for example, yttrium-containing materials such as Y₂O₃ or YF₃ may be used.

In an embodiment, the plasma processing apparatus 1 may be configured as part of a substrate processing system.

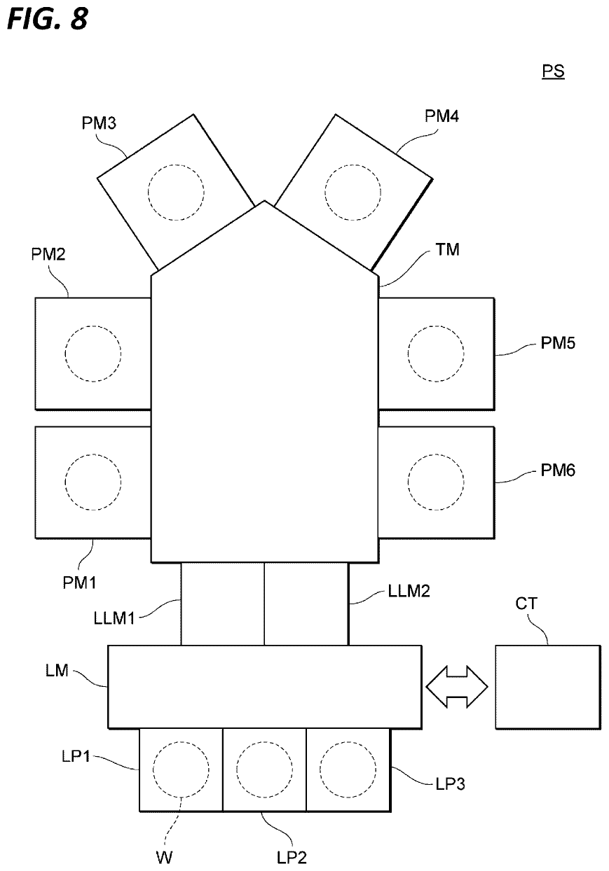

FIG. 8 is a view schematically illustrating a substrate processing system (hereinafter referred to as a “substrate processing system PS”) according to an embodiment.

The substrate processing system PS includes substrate processing chambers PM1 to PM6 (hereinafter collectively referred to as “substrate processing modules PM”), a transfer module TM, load-lock modules LLM1 and LLM2 (hereinafter collectively referred to as “load-lock modules LLM”), a loader module LM, and load ports LP1 to LP3 (hereinafter collectively referred to as “load ports LP”). A control unit CT controls each component of the substrate processing system PS to perform a given processing on a substrate W.

The substrate processing modules PM perform processing, such as etching, trimming, film formation, annealing, doping, lithography, cleaning, and ashing, respectively, on substrates W therein. At least one of the substrate processing chambers PM1 to PM6 may be the plasma processing apparatus 1 illustrated in FIG. 1. In addition, at least one of the substrate processing chambers PM1 to PM6 may be a plasma processing apparatus that uses any plasma source, such as an inductively coupled plasma or microwave plasma. At least one of the substrate processing chambers PM1 to PM6 may be a measurement module that measures the thickness of a film formed on a substrate W or the dimensions of a pattern formed on a substrate W using, for example, an optical method.

The transfer module TM has a transfer apparatus that transfers substrates W, and transfers substrates W between the substrate processing modules PM or between the substrate processing modules PM and the load-lock modules LLM. The transfer apparatus may include a sensor configured to measure the moisture concentration in the plasma processing space 10s described above. Using this sensor, step ST6 (a step of measuring the moisture concentration in the plasma processing space 10s after step ST3) may be performed. The sensor may be provided, for example, on an arm that places or holds the substrate W in the transfer apparatus. The substrate processing modules PM and the load-lock modules LLM are arranged adjacent to the transfer module TM. The transfer module TM and the substrate processing modules PM and load-lock modules LLM are spatially isolated or connected by gate valves capable of being opened and closed.

The load-lock modules LLM1 and LLM2 are provided between the transfer module TM and the loader module LM. The load-lock modules LLM may switch the internal pressures thereof to atmospheric pressure or vacuum. The “atmospheric pressure” may be the pressure outside each module included in the substrate processing system PS1. The term “vacuum” refers to a pressure lower than atmospheric pressure, which may be, for example, a medium vacuum ranging from 0.1 Pa to 100 Pa. The load-lock modules LLM transfer substrates W from the loader module LM at atmospheric pressure to the transfer module TM in a vacuum, and also transfer substrates W from the transfer module TM in a vacuum to the loader module LM at atmospheric pressure.

The loader module LM includes a transfer apparatus configured to transfer substrates W between the load-lock modules LLM and the load ports LP. The interiors of the load ports LP may each accommodate, for example, a front opening unified pod (FOUP) capable of storing 25 substrates W or an empty FOUP. The loader module LM takes out substrates W from the FOUPs in the load ports LP and transfers the substrates to the load-lock modules LLM. In addition, the loader module LM takes out substrates W from the load-lock modules LLM and transfers the substrates to the FOUPs in the load ports LP.

The control unit CT controls each component of the substrate processing system PS to perform given processing on the substrates W. The control unit CT stores recipes that define, for example, a process sequence, process conditions, and transfer conditions, and in accordance with the recipes, the control unit CT controls each component of the substrate processing system PS to perform given processing on the substrates W. The control unit CT may share some or all of the functions of the control unit 2 illustrated in FIG. 1.

Embodiments of the present disclosure further includes the following aspects.

(Appendix 1) A plasma processing apparatus including:

a chamber;

a substrate support provided within the chamber;

a gas supply port connected to a source of a processing gas containing hydrogen fluoride gas, the gas supply port being configured to supply the processing gas into the chamber; and a plasma generator configured to generate plasma from the processing gas,

wherein at least a portion of an interior of the chamber is made of a material containing at least one material selected from carbon, tungsten, molybdenum, ruthenium, titanium nitride, samarium, and yttrium.

(Appendix 2) The plasma processing apparatus described in Appendix 1, wherein the material is a carbon-containing material.

(Appendix 3) The plasma processing apparatus described in Appendix 1 or 2, wherein the carbon-containing material is at least one material selected from diamond, graphite, diamond-like carbon, silicon carbide, tungsten carbide, and boron carbide.

(Appendix 4) The plasma processing apparatus described in any one of Appendixes 1 to 3, wherein the material is a tungsten-containing material.

(Appendix 5) The plasma processing apparatus described in any one of Appendixes 1 to 4, wherein the tungsten-containing material is at least one material selected from tungsten carbide, tungsten silicide, tungsten oxide, tungsten nitride, tungsten silicon nitride, and tungsten silicon carbide.

(Appendix 6) The plasma processing apparatus described in any one of Appendixes 1 to 5, wherein an area within the chamber exposed to the plasma is at least partially made of the material.

(Appendix 7) The plasma processing apparatus described in any one of Appendixes 1 to 6, wherein an area in the chamber exposed to the plasma is entirely made of the material.

(Appendix 8) The plasma processing apparatus described in Appendix 7, wherein the material is a tungsten-containing material.

(Appendix 9) The plasma processing apparatus described in any one of Appendixes 1 to 8, wherein the chamber has an area made of a silicon-containing material, and the area is at least partially coated with the material.

(Appendix 10) The plasma processing apparatus described in Appendix 9, wherein the coating is a deposited film or a thermally sprayed film containing at least one material selected from carbon, tungsten, molybdenum, ruthenium, titanium nitride, samarium, and yttrium.

(Appendix 11) The plasma processing apparatus described in any one of Appendixes 1 to 10, wherein the chamber has a temperature-controllable area which is made of the material.

(Appendix 12) The plasma processing apparatus described in Appendix 11, wherein the temperature-controllable area is in thermal contact with a flow path through which a heat transfer fluid flows.

(Appendix 13) The plasma processing apparatus described in any one of Appendixes 1 to 12, wherein the plasma processing apparatus further includes: a showerhead disposed above the substrate support and provided with a plurality of gas supply ports, and the showerhead is at least partially made of the material.

(Appendix 14) The plasma processing apparatus described in any one of Appendixes 1 to 13, wherein the plasma processing apparatus further includes: an edge ring disposed to surround the substrate disposed on the substrate support, and the edge ring is at least partially made of the material.

(Appendix 15) The plasma processing apparatus described in any one of Appendixes 1 to 14, wherein an inner wall of the chamber is at least partially made of the material.

(Appendix 16) The plasma processing apparatus described in any one of Appendixes 1 to 15, further includes: a baffle plate that separates the interior of the chamber into a plasma processing space, where the plasma is generated, and an exhaust space configured to exhaust gas from the interior of the chamber, and the baffle plate is at least partially made of the material.

(Appendix 17) The plasma processing apparatus described in any one of Appendixes 1 to 16, further includes: a controller configured to:
(a) provide a substrate having a silicon-containing film and a mask on the silicon-containing film onto the substrate support;
(b) supply the processing gas into the chamber through the gas supply port; and
(c) etch the silicon-containing film by generating the plasma from the processing gas using the plasma generator.

(Appendix 18) The plasma processing apparatus described in Appendix 17, wherein the mask is a carbon-containing film, a tungsten-containing film, a polysilicon-containing film, a ruthenium-containing film, a titanium nitride-containing film, a silicon boride-containing film, a samarium-containing film, or an yttrium-containing film.

(Appendix 19) The plasma processing apparatus described in Appendix 17 or 18, wherein the gas supply port is connected to a source of a carbon-containing gas or a tungsten-containing gas,

wherein the controller is further configured to: (d) supply the carbon-containing gas or the tungsten-containing gas into the chamber to generate plasma after (c).

(Appendix 20) The plasma processing apparatus described in any one of Appendixes 17 to 19, wherein all areas in the chamber exposed to the plasma are made of the material, and the mask contains the material.

(Appendix 21) The plasma processing apparatus described in any one of Appendixes 1 to 20, wherein the plasma processing apparatus further includes: a sensor configured to measure a moisture concentration within the chamber.

(Appendix 22) A substrate processing system including:

the plasma processing apparatus described in any one of Appendixes 1 to 21;

a transfer chamber; and a transfer apparatus configured to transfer a substrate from the transfer chamber into the chamber of the plasma processing apparatus,

wherein the transfer apparatus includes a sensor configured to measure a moisture concentration within the chamber.

(Appendix 23) A plasma processing apparatus including:

a chamber;

a substrate support provided within the chamber;

a gas supply port connected to a source of a processing gas and configured to supply the processing gas into the chamber;

a plasma generator configured to generate plasma containing hydrogen fluoride (HF) species from the processing gas,

wherein the chamber is at least partially made of a material selected from carbon, tungsten, molybdenum, ruthenium, titanium nitride, samarium, and yttrium.

(Appendix 24) The plasma processing apparatus described in Appendix 23, wherein the processing gas contains at least one gas selected from hydrogen fluoride gas, hydrofluorocarbon gas, hydrofluorocarbon gas having two or more carbon atoms, and a mixed gas of a hydrogen-containing gas and a fluorine-containing gas.

(Appendix 25) The plasma processing apparatus described in Appendix 17, wherein the gas supply port is further connected to a source of a cleaning gas containing hydrogen,

after performing a cycle that includes (a) to (c) one or more times, the controller is further configured to:
(e) supply the cleaning gas into the chamber; and
(f) clean the interior of the chamber by generating plasma from the cleaning gas using the plasma generator.

(Appendix 26) The plasma processing apparatus described in Appendix 25, wherein the hydrogen-containing gas is at least one of hydrogen gas and hydrocarbon gas.

(Appendix 27) A plasma processing apparatus including:

a chamber;

a substrate support provided within the chamber;

a gas supply port connected to a source of a processing gas containing hydrogen fluoride gas, the gas supply port being configured to supply the processing gas into the chamber;

a plasma generator configured to generate plasma from the processing gas; and

a controller,

wherein the controller is configured to:
(a) provide a substrate having a silicon-containing film and a mask on the silicon-containing film onto the substrate support;
(b) supply the processing gas into the chamber through the gas supply port; and
(c) etch the silicon-containing film by generating the plasma from the processing gas using the plasma generator,

wherein (a) to (c) are executed while at least a portion of parts within the chamber is at least partially made of a material containing at least one material selected from carbon, tungsten, molybdenum, ruthenium, titanium nitride, samarium, and yttrium.

(Appendix 28) The plasma processing apparatus described in Appendix 27, wherein the gas supply port is further connected to a source of a precoat gas containing at least one material selected from carbon, tungsten, molybdenum, ruthenium, titanium nitride, samarium, and yttrium, and

the controller is further configured to form a precoat on at least a portion of the parts within the chamber with the precoat gas before (a).

(Appendix 29) The plasma processing apparatus described in Appendix 28, wherein the precoat gas contains at least one gas selected from hydrocarbon, halogenated tungsten, and halogenated molybdenum.

(Appendix 30) The plasma processing apparatus described in any one of Appendixes 27 to 29, wherein the gas supply port is further connected to a source of a cleaning gas containing hydrogen,

after performing a cycle that includes (a) to (c) once or more times, the controller is further configured to:
(e) supply the cleaning gas into the chamber; and
(f) clean an interior of the chamber by generating plasma from the cleaning gas using the plasma generator.

According to an embodiment of the present disclosure, it may be possible to provide a technique for suppressing a decrease in etching rate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber;
a substrate support provided within the chamber;
a gas supply port connected to a source of a processing gas containing hydrogen fluoride gas, and configured to supply the processing gas into the chamber; and
a plasma generator configured to generate a plasma from the processing gas,
wherein at least a portion of an interior of the chamber is made of a material containing at least one material selected from carbon, tungsten, molybdenum, ruthenium, titanium nitride, samarium, and yttrium.

2. The plasma processing apparatus according to claim 1, wherein the material is a carbon-containing material.

3. The plasma processing apparatus according to claim 2, wherein the carbon-containing material is at least one material selected from diamond, graphite, diamond-like carbon, silicon carbide, tungsten carbide, and boron carbide.

4. The plasma processing apparatus according to claim 1, wherein the material is a tungsten-containing material.

5. The plasma processing apparatus according to claim 4, wherein the tungsten-containing material is at least one material selected from tungsten carbide, tungsten silicide, tungsten oxide, tungsten nitride, tungsten silicon nitride, and tungsten silicon carbide.

6. The plasma processing apparatus according to claim 1, wherein an area within the chamber exposed to the plasma is at least partially made of the material.

7. The plasma processing apparatus according to claim 1, wherein an area in the chamber exposed to the plasma is entirely made of the material.

8. The plasma processing apparatus according to claim 7, wherein the material is a tungsten-containing material.

9. The plasma processing apparatus according to claim 1, wherein the chamber has an area made of a silicon-containing material, and the area is at least partially coated with the material.

10. The plasma processing apparatus according to claim 9, wherein the coating is a deposited film or a thermally sprayed film containing at least one material selected from carbon, tungsten, molybdenum, ruthenium, titanium nitride, samarium, and yttrium.

11. The plasma processing apparatus according to claim 1, wherein the chamber has a temperature-controllable area that is at least partially made of the material.

12. The plasma processing apparatus according to claim 11, wherein the temperature-controllable area is in thermal contact with a flow path through which a heat transfer fluid flows.

13. The plasma processing apparatus according to claim 1, further comprising:
a showerhead disposed above the substrate support and provided with a plurality of gas supply ports, the showerhead being at least partially made of the material.

14. The plasma processing apparatus according to claim 1, further comprising:
an edge ring disposed to surround the substrate disposed on the substrate support, the edge ring being at least partially made of the material.

15. The plasma processing apparatus according to claim 1, wherein an inner wall of the chamber is at least partially made of the material.

16. The plasma processing apparatus according to claim 1, further comprising:
a baffle plate configured to separate the interior of the chamber into a plasma processing space where the plasma is generated, and an exhaust space where a gas is exhausted from the interior of the chamber, the baffle plate being at least partially made of the material.

17. The plasma processing apparatus according to claim 1, further comprising:
a controller configured to:
(a) provide a substrate including a silicon-containing film and a mask on the silicon-containing film onto the substrate support;
(b) supply the processing gas into the chamber through the gas supply port; and
(c) etch the silicon-containing film by generating the plasma from the processing gas using the plasma generator.

18. The plasma processing apparatus according to claim 17, wherein the mask is a carbon-containing film, a tungsten-containing film, a polysilicon-containing film, a ruthenium-containing film, a titanium nitride-containing film, a silicon boride-containing film, a samarium-containing film, or an yttrium-containing film.

19. The plasma processing apparatus according to claim 17, wherein the gas supply port is connected to a source of a carbon-containing gas or a tungsten-containing gas, and
the controller is further configured to:
(d) supply the carbon-containing gas or the tungsten-containing gas into the chamber to generate plasma after (c).

20. The plasma processing apparatus according to claim 17, wherein all areas in the chamber exposed to the plasma are made of the material, and the mask contains the material.

21. The plasma processing apparatus according to claim 1, further comprising:
a sensor configured to measure a moisture concentration within the chamber.

22. A substrate processing system comprising:
the plasma processing apparatus according to claim 1;
a transfer chamber; and
a transfer apparatus configured to transfer a substrate from the transfer chamber into the chamber of the plasma processing apparatus,
wherein the transfer apparatus includes a sensor that measures a moisture concentration within the chamber.

23. A plasma processing apparatus comprising:
a chamber;
a substrate support provided within the chamber;
a gas supply port connected to a source of a processing gas and configured to supply the processing gas into the chamber;
a plasma generator configured to generate plasma containing hydrogen fluoride (HF) species from the processing gas,
wherein the chamber is at least partially made of a material selected from carbon, tungsten, molybdenum, ruthenium, titanium nitride, samarium, and yttrium.

24. The plasma processing apparatus according to claim 23, wherein the processing gas contains at least one selected from hydrogen fluoride gas, hydrofluorocarbon gas, hydrofluorocarbon gas having two or more carbon atoms, and a mixed gas of a hydrogen-containing gas and a fluorine-containing gas.

25. The plasma processing apparatus according to claim 17, wherein the gas supply port is further connected to a source of a cleaning gas containing a hydrogen-containing gas, and
after performing a cycle that includes (a) to (c) one or more times, the controller is further configured to:
(e) supply the cleaning gas into the chamber; and
(f) generate a plasma from the cleaning gas using the plasma generator, thereby cleaning the interior of the chamber.

26. The plasma processing apparatus according to claim 25, wherein the hydrogen-containing gas is at least one of hydrogen gas and hydrocarbon gas.

27. A plasma processing apparatus comprising:
a chamber;
a substrate support provided within the chamber;
a gas supply port connected to a source of a processing gas containing hydrogen fluoride gas, and configured to supply the processing gas into the chamber;
a plasma generator configured to generate plasma from the processing gas; and
a controller,
wherein the controller is configured to:
(a) provide a substrate having a silicon-containing film and a mask on the silicon-containing film onto the substrate support;
(b) supply the processing gas into the chamber through the gas supply port; and
(c) etch the silicon-containing film by generating the plasma from the processing gas using the plasma generator,
wherein (a) to (c) are executed while at least a portion of parts within the chamber are made of a material containing at least one selected from carbon, tungsten, molybdenum, ruthenium, titanium nitride, samarium, and yttrium.

28. The plasma processing apparatus according to claim 27, wherein the gas supply port is further connected to a source of a precoat gas containing at least one material selected from carbon, tungsten, molybdenum, ruthenium, titanium nitride, samarium, and yttrium, and
the controller is further configured to form a precoat on at least a portion of the parts within the chamber with the precoat gas before (a).

29. The plasma processing apparatus according to claim 28, wherein the precoat gas contains at least one selected from hydrocarbon, halogenated tungsten, and halogenated molybdenum.

30. The plasma processing apparatus according to claim 27, wherein the gas supply port is further connected to a source of a cleaning gas containing hydrogen, and
after performing a cycle that includes (a) to (c) once or more times, the controller is further configured to:
(e) supply the cleaning gas into the chamber; and
(f) clean an interior of the chamber by generating plasma from the cleaning gas using the plasma generator.
